(19) United States
(12) Patent Application Publication
(10) Pub. No.: US 2026/0082756 A1
(43) Pub. Date: Mar. 19, 2026

(54) SEMICONDUCTOR STRUCTURE AND METHOD FOR MANUFACTURING THEREOF

(71) Applicant: ENKRIS SEMICONDUCTOR, INC., Suzhou (CN)

(72) Inventor: Yudong CHENG, Suzhou (CN)

(21) Appl. No.: 19/023,204

(22) Filed: Jan. 15, 2025

(30) Foreign Application Priority Data
Sep. 14, 2024 (CN) 202411295524.8

(51) Int. Cl. H10H 29/856; H10H 29/01; H10H 29/14; H10H 29/80

(52) U.S. Cl. CPC H10H 29/856; H10H 29/032; H10H 29/034; H10H 29/0363; H10H 29/14; H10H 29/8323; H10H 29/8421

(57) ABSTRACT

The disclosure provides a semiconductor structure and a method for manufacturing thereof. The semiconductor structure includes a substrate, a light-emitting pixel layer on the substrate, and reflective parts. The substrate includes a first surface and a second surface opposite to the first surface, the first surface includes a convex parts, and each of the convex parts protrudes in a direction away from the second surface; the light-emitting pixel layer includes at least one light-emitting pixel including a first semiconductor layer, a light-emitting layer and a second semiconductor layer which are sequentially disposed on the second surface, and conductivity types of the first semiconductor layer and the second semiconductor layer are opposite; and the reflection parts are conformally formed on the convex parts, and the reflection parts and the convex parts are in one-to-one correspondence in position.

### CROSS REFERENCE TO RELATED APPLICATIONS

This application claims priority to Chinese Patent Application No. 2024112955248 entitled “SEMICONDUCTOR STRUCTURE AND METHOD FOR MANUFACTURING THEREOF” filed on Sep. 14, 2024, the entire content of which is incorporated herein by reference.

### TECHNICAL FIELD

The disclosure relates to the technical field of semiconductors, in particular to a semiconductor structure and a method for manufacturing thereof.

### BACKGROUND

Currently, Micro LEDs (Micro Light Emitting Diode) are widely used in display fields such as the near-to-eye display and the wearable display. However, for the applications of the Micro LED technology in the fields such as VR (Virtual Reality)/AR (Augmented Reality), it is required that the light emitted by the light-emitting pixels in the Micro LED has a relatively small divergence angle. Light exceeding the divergence angle threshold will become stray light, which results in low luminance of the Micro LED.

To improve the luminance of the Micro LED, the present disclosure provides a semiconductor structure and a method for manufacturing thereof.

### SUMMARY

In view of this, the present disclosure provides a semiconductor structure and a manufacturing method thereof.

In the first aspect, the present disclosure provides a semiconductor structure, including:
a substrate including a first surface and a second surface opposite to the first surface, where the first surface includes convex parts, and each of the convex parts protrudes in a direction away from the second surface;
a light-emitting pixel layer on the second surface, where the light-emitting pixel layer includes at least one light-emitting pixel each including a first semiconductor layer, a light-emitting layer and a second semiconductor layer which are sequentially disposed on the second surface, and the conductivity types of the first semiconductor layer and the second semiconductor layer are opposite; and
reflective parts conformally formed on the convex parts, where the reflective parts and the convex parts are in one-to-one correspondence in position.

In the second aspect, the present disclosure provides a method for manufacturing a semiconductor structure, including:
providing a substrate;
forming a light-emitting pixel layer on the substrate, where the light-emitting pixel layer includes at least one light-emitting pixel including a first semiconductor layer, a light-emitting layer and a second semiconductor layer which are sequentially disposed on the substrate, and conductivity types of the first semiconductor layer and the second semiconductor layer are opposite;

etching the substrate to form convex parts on a first surface of the substrate away from the first semiconductor layer; and
forming reflection parts on the convex parts conformally, where the reflection parts and the convex parts are in one-to-one correspondence in position.

According to the semiconductor structure and the method for manufacturing thereof provided by the present disclosure, arc-shaped reflection parts are formed on the substrate with convex parts, in this way, not only the small-angle light emitted by the light-emitting pixel layer toward the reflective part will be reflected by the reflective part to emit out at the front surface of the semiconductor structure, but also the large-angle light emitted by the light-emitting pixel layer toward the reflective part will be reflected by the reflective part to emit out at the front surface of the semiconductor structure, and the light emitted by the light-emitting pixel layer is converged, thereby improving the light-extraction efficiency and the luminance at the front of the semiconductor structure.

### BRIEF DESCRIPTION OF DRAWINGS

FIG. 1A, FIG. 1B and FIG. 1C are schematic cross-sectional structural diagrams of a semiconductor structure according to an embodiment of the present disclosure.

FIG. 2A, FIG. 2B, FIG. 2C, FIG. 2D, FIG. 2E, FIG. 2F, FIG. 2G and FIG. 2H are schematic cross-sectional structural diagrams of a semiconductor structure according to an embodiment of the present disclosure.

FIG. 3A, FIG. 3B and FIG. 3C are schematic cross-sectional structural diagrams of a semiconductor structure according to an embodiment of the present disclosure.

FIGS. 4 and 5 are schematic cross-sectional structural diagrams of a semiconductor structure according to an embodiment of the present disclosure.

FIGS. 6 and 7 are schematic cross-sectional structural diagrams of a semiconductor structure according to an embodiment of the present disclosure.

FIG. 8 is a flowchart of a method for manufacturing a semiconductor structure according to an embodiment of the present disclosure.

FIGS. 9 to 14 are schematic diagrams of intermediate structures formed in a process of manufacturing a semiconductor structure.

### DETAILED DESCRIPTION

Exemplary embodiments will be described in detail herein, examples of which are illustrated in the accompanying drawings. When the following descriptions involve the drawings, like numerals in different drawings refer to like or similar elements unless otherwise indicated. Embodiments described in the exemplary embodiments below are not intended to represent all embodiments consistent with the present disclosure. Rather, they are merely embodiments of devices and methods consistent with some aspects of the present disclosure as recited in the appended claims.

Terms used in the present disclosure are only for the purpose of describing embodiments and are not intended to limit the present disclosure. As used in the present disclosure and the appended claims, the singular forms “a”, “said” and “the” are intended to include the plural forms as well, unless the context clearly dictates otherwise. It should also be understood that the term “and/or” used herein includes any and all possible combinations of one or more of the associated listed items.

It should be understood that although the terms first, second, third, etc. may be used in the present disclosure to describe various information, such information should not be limited to these terms. These terms are only used to distinguish information of the same category with each other. For example, without departing from the scope of the present disclosure, the first information may also be referred to as the second information, and similarly, the second information may also be referred to as the first information. Depending on the context, the word “if” as used herein may be interpreted as “when” or “upon” or “in response to determining”.

### Embodiment 1

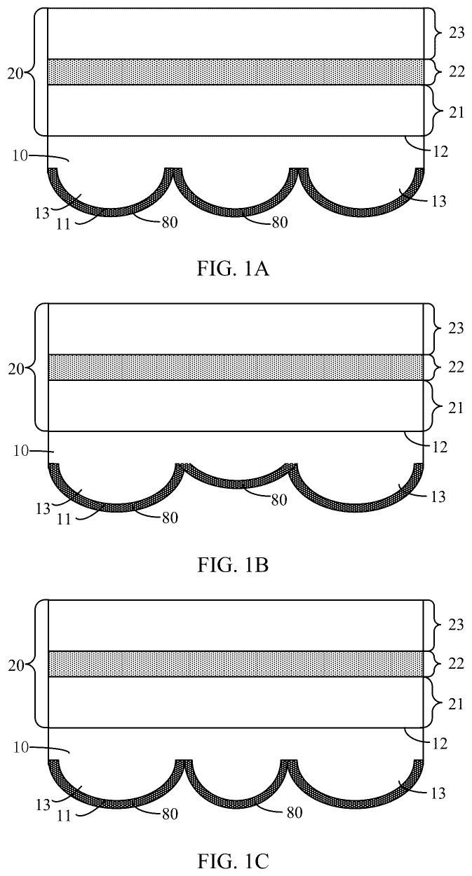

To improve the luminance of the LED structure, the Embodiment 1 of the present disclosure provides a semiconductor structure. FIG. 1A, FIG. 1B and FIG. 1C are schematic cross-sectional structural diagrams of a semiconductor structure according to an embodiment of the present disclosure. As shown in FIG. 1A, the semiconductor structure includes:
a substrate 10 including a first surface 11 and a second surface 12 opposite to the first surface 11, where the first surface 11 includes convex parts 13, and each of the convex parts 13 protrudes in a direction away from the second surface 12;

a light-emitting pixel layer 20 on the second surface 12, where the light-emitting pixel layer 20 includes at least one light-emitting pixel including a first semiconductor layer 21, a light-emitting layer 22 and a second semiconductor layer 23 which are sequentially disposed on the second surface 12, and the conductivity types of the first semiconductor layer 21 and the second semiconductor layer 23 are opposite; and
reflective parts 80 conformally formed on the convex parts 13, where the reflective parts 80 and the convex parts 13 are in one-to-one correspondence in position.

In some embodiments, the substrate 10 is transparent, and the substrate 10 is made of at least one of sapphire, silicon, silicon carbide, a GaN-based material, or AlN. The first surface 11 includes convex parts 13, that is, the part of the substrate 10 away from the second surface 12 includes convex parts 13. The shape of the convex part 13 may be a partial sphere or a partial cylinder. For example, the shape of the convex part 13 is a one-third spherical, a hemispherical, a one-third cylindrical, a semi-cylindrical, or the like. Optionally, when the substrate 10 is made of multiple of sapphire, silicon, silicon carbide, GaN-based material, and AlN, the convex part 13 includes sub-layers with different refractive indexes, and the sub-layers with different refractive indexes are designed for the convex part 13, so that the light emitted by the light-emitting pixel layer 20 can be further changed, thereby improving the collimation of the light emitted by the semiconductor structure. In some embodiments, the first semiconductor layer 21 may be an N-type semiconductor layer, the light emitting layer 22 may be a single quantum well layer or a multiple quantum well layer, and the second semiconductor layer 23 may be a P-type semiconductor layer. The first semiconductor layer 21, the light emitting layer 22 and the second semiconductor layer 23 are made of a group III nitride material, for example, the first semiconductor layer 21, the light emitting layer 22 and the second semiconductor layer 23 may be made of at least one of GaN, AlN, InN, AlGaN, InGaN, AlInGaN, AlInN, GaAs and AlGaAs, and the forming process may include: atomic layer deposition (ALD), chemical vapor deposition (CVD), molecular beam epitaxy (MBE), plasma enhanced chemical vapor deposition (PECVD), low pressure chemical vapor deposition (LPCVD), metal-organic chemical vapor deposition (MOCVD) or a combination thereof.

In some embodiments, the reflective parts 80 are conformally formed on the convex parts 13 respectively, and the reflective parts 80 and the convex parts 13 are in one-to-one correspondence in position. In other words, an orthographic projection of a reflective part 80 on the second surface 12 may coincide with the orthographic projection of a convex part 13 on the second surface 12. The reflective part 80 is used for reflecting the light emitted by the light-emitting pixel and adjusting an outgoing direction and/or an outgoing angle of the light. The reflective part 80 may be made of metal reflective material, for example, the reflective part 80 may be an Ag layer, or the reflective part 80 may include at least two alternating layers, in which a layer is made of Ni, and the other layer is made of Ag. Since the convex part 13 protrudes in a direction away from the second surface 12, the formed reflective part 80 protrudes in a direction away from the second surface 12, that is, the reflective part 80 is approximately arc-shaped, in this way, not only the small-angle light emitted by the light-emitting pixel layer 20 toward the reflective part 80 will be reflected by the reflective part 80 to emit out at the front surface of the semiconductor structure, but also the large-angle light emitted by the light-emitting pixel layer 20 toward the reflective part 80 will be reflected by the reflective part 80 to emit out at the front surface of the semiconductor structure, and thus the light emitted by the light-emitting pixel layer 20 is converged, thereby improving the light-extraction efficiency and the luminance at the front of the semiconductor structure. Optionally, the light-emitting pixels are on the focal plane of the convex part 13, which can further control the light emitted by the light-emitting pixel layer 20, thereby improving the collimation of the light emitted by the semiconductor structure. It should be noted that “to emit out at the front surface of the semiconductor structure” refers to that the light emitted by the light-emitting layer 22 is emitted out from a side of the light-emitting pixel away from the substrate 10. The small-angle light refers to light with a small angle between the outgoing direction thereof and the normal line of the second surface 12; and the large-angle light refers to light with a large angle between the outgoing direction thereof and the normal line of the second surface 12.

In some embodiments, one of the convex parts 13 has a different size than another of the convex parts 13, and optionally, at least one of the convex parts 13 has a different thickness (as shown in FIG. 1B) or radius of curvature (as shown in FIG. 1C) than others of the convex parts 13. By adjusting the sizes of the convex parts 13, the light emitted by the light-emitting pixel layer 20 can be further controlled, and the light emission uniformity of the light-emitting pixel layer 20 is improved. The thickness of the convex part 13 refers to the farthest distance between the convex part 13 and the second surface 12 in the normal direction of the second surface 12.

### Embodiment 2

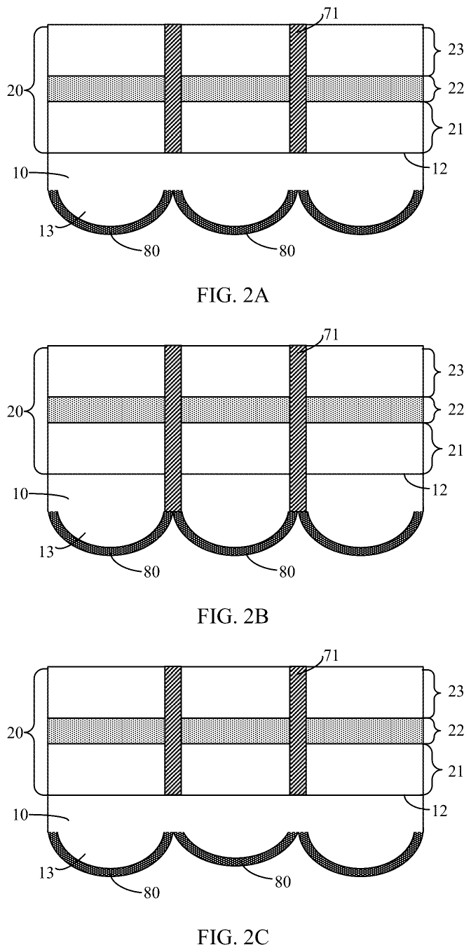

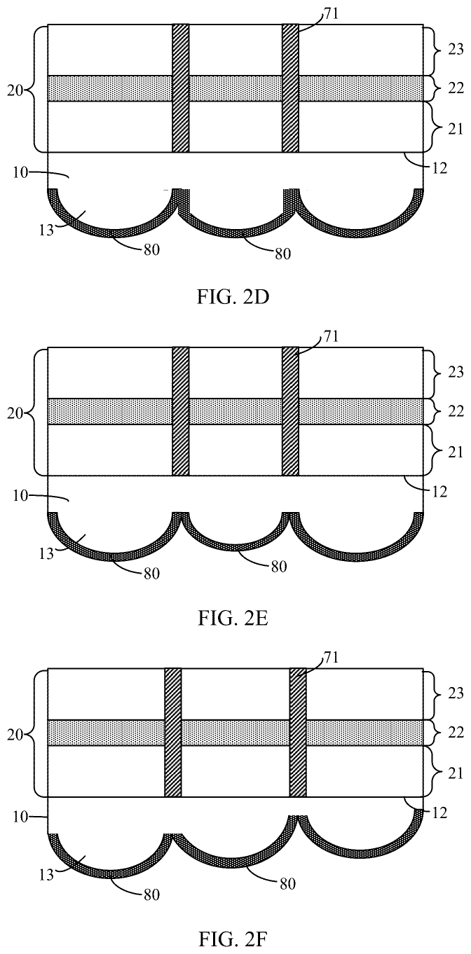

The content of the Embodiment 2 is substantially the same as the content of the Embodiment 1, and the differences between the Embodiment 2 and the Embodiment 1 are described below. FIG. 2A, FIG. 2B, FIG. 2C, FIG. 2D, FIG. 2E, FIG. 2F, FIG. 2G and FIG. 2H are schematic cross-sectional structural diagrams of a semiconductor structure according to an embodiment of the present disclosure. As shown in FIG. 2A, the light-emitting pixel layer 20 includes light-emitting pixels, and the light-emitting pixels are separated by an isolation structure 71, that is, an isolation structure 71 is provided between the adjacent light-emitting pixels. The isolation structure 71 is used for isolating the light emitted by the adjacent light-emitting pixels to avoid the crosstalk between the adjacent light-emitting pixels. The isolation structure 71 penetrates through the light-emitting pixel layer 20, and the isolation structure 71 may be made of an insulating black glue. In some embodiments, as shown in FIG. 2B, the isolation structure 71 penetrates through the light-emitting pixel layer 20 and penetrates through the substrate 10, thereby further reducing the crosstalk between the adjacent light-emitting pixels. In some embodiments, if the light-emitting pixels are not used for displaying images, but are only used for emitting light, the isolation structure between the adjacent light-emitting pixels may not be provided.

In some embodiments, as shown in FIG. 2C, in the convex parts 13 corresponding to the light-emitting pixels, at least one of the convex parts 13 has a different size than other convex parts 13, and optionally, in the convex parts 13, at least one of the convex parts 13 has a different thickness or radius of curvature than other convex parts 13. By adjusting the sizes of the convex parts 13, the light emitted by the light-emitting pixel layer 20 can be further controlled, and the light emission uniformity of different light-emitting pixels can be improved.

In some embodiments, the at least one light-emitting pixel includes light-emitting pixels, and in the light-emitting pixels, a projection area of one of the at least one light-emitting pixel on the plane of the substrate 10 is different from a projection area of another of the at least one light-emitting pixel on the plane of the substrate 10. Optionally, as shown in FIG. 2D, a curvature radius and a thickness of a convex part 13 corresponding to a first light-emitting pixel of the light-emitting pixels with a first projection area on the plane of the substrate 10 are both same as a curvature radius and a thickness of a convex part 13 corresponding to a second light-emitting pixel of the light-emitting pixels with a second projection area on the plane of the substrate, and a width of the convex part 13 corresponding to the first light-emitting pixel is smaller than a width of the convex part 13 corresponding to the second light-emitting pixel, where the first projection area is smaller than the second projection area. To keep the curvature radius and the thickness of the convex part 13 unchanged, the size of the light-emitting pixel is small, and the width of the corresponding convex part 13 is small, as shown in FIG. 2D, the thickness of the arc portion of the convex part 13 is smaller, and the thickness of the plane portion is larger, so that it can be ensured that the light-emitting pixels with different sizes are all on the focal plane of the convex part 13. Optionally, as shown in FIG. 2E, a curvature radius and a thickness of a convex part 13 corresponding to a first light-emitting pixel of the light-emitting pixels with a first projection area on the plane of the substrate 10 are both smaller than a curvature radius and a thickness of a convex part 13 corresponding to a second light-emitting pixel of the light-emitting pixels with a second projection area on the plane of the substrate 10, and a width of the convex part 13 corresponding to the first light-emitting pixel is smaller than a width of the convex part 13 corresponding to the second light-emitting pixel, wherein the first projection area is smaller than the second projection area, and the change trends of a curvature radius and a thickness for the convex part 13 are the same as the change trend of the size for the light-emitting pixel. Optionally, the light-emitting colors of the light-emitting pixels include red, blue, or green, a projection area of the red light-emitting pixel on the plane of the substrate 10 is greater than a projection area of the green light-emitting pixel on the plane of the substrate 10, and a projection area of the blue light-emitting pixel on the plane of the substrate 10 is greater than a projection area of the green light-emitting pixel on the plane of the substrate 10. In the green light spectrum region around the wavelength 555 nm, the sensitivity of the human eye is the highest, while in the region with longer wavelength (such as red light) or shorter wavelength (such as blue light), the sensitivity of the human eye is reduced, which indicates that a higher radiation power is required in these wavelength regions to acquire the same brightness perception. By changing the sizes of the light-emitting pixels with different colors, the brightness perception of different light-emitting wavelength regions can be adjusted, for example, larger light-emitting pixels emit red light and blue light, and a smaller light-emitting pixel emit green light, thereby improving the brightness perception of the red light and the blue light. Therefore, the size of the light-emitting pixel can be changed, and the size of the convex part 13 corresponding to the light-emitting pixel can be further adjusted to adjust and control the light emitted by the light-emitting pixel layer 20.

In some embodiments, since the uLED is generally smaller than 100 μm, the curvature radius of the convex part 13 is smaller than 100 μm, the distance from the light-emitting layer 22 to the convex part 13 is x times the curvature radius of the convex part 13, x ranges from 0.3-0.7, and the distance from the light-emitting layer 22 to the convex part 13 refers to the distance from the light-emitting layer 22 to the convex part 13 farthest from the light-emitting layer 22. Optionally, the light-emitting layer 22 is on the focal plane of the convex part 13, that is, the distance from the light-emitting layer 22 to the convex part 13 is 0.5 times the curvature radius of the convex part 13, so that the light emitted by the light-emitting pixel layer 20 can be further controlled, thereby improving the collimation of the light emitted by the semiconductor structure. As shown in FIG. 2F, the light-emitting colors of the light-emitting pixels include red, blue or green, the thickness of the convex part 13 corresponding to the red light-emitting pixel is greater than the thickness of the convex part 13 corresponding to the green light-emitting pixel, and the thickness of the convex part 13 corresponding to the green light-emitting pixel is greater than the thickness of the convex part 13 corresponding to the blue light-emitting pixel. When the light-emitting color of the light-emitting pixel includes red, blue or green, the frequency of red light is lower, the refractive index in the medium is smaller, and since the larger the refractive index is, the shorter the focal length is, the focal length of the red light is longest. To make the light-emitting pixels emitting red light, green light and blue light all on the focal plane of the convex part 13, the thickness of the convex part 13 corresponding to the red light-emitting pixel may be designed to be maximum, the thickness of the convex part 13 corresponding to the green light-emitting pixel may be mediate, and the thickness of the convex part 13 corresponding to the blue light-emitting pixel may be designed to be minimum.

As shown in FIG. 2G, the semiconductor structure provided in this embodiment of the present disclosure further includes a DBR (distributed Bragg reflector) layer 60 on the second semiconductor layer 23, where the DBR layer 60 includes at least one DBR structure 61, and the at least one DBR structure 61 and the at least one light-emitting pixel are in one-to-one correspondence in position. In other words, an orthographic projection of a DBR structure 61 on the second surface 12 coincides with an orthographic projection of a light-emitting pixel on the second surface 12. To make the light emit out from the front surface of the semiconductor structure, the reflectivity of the reflective part 80 is greater than the reflectivity of the DBR layer 60, for example, the reflective part 80 may be an Ag layer, and the DBR layer may be a stacked material layers of SiO₂/SiN. In this way, through the synergistic effect of the arc-shaped reflective part 80 at bottom and the DBR layer 60 at the top, the divergence angle of the light emitted by the light emitting layer 22 can be controlled, thereby improving the collimation of the light emitted by the semiconductor structure.

In some embodiments, the convex parts 13, the light-emitting pixels, and the DBR structures 61 may be in one-to-one correspondence in position, that is, the orthographic projections of the convex parts 13, the light-emitting pixels, and the DBR structures 61 on the second surface 12 coincide with each other and are in one-to-one correspondence.

As shown in FIG. 2H, the semiconductor structure provided in this embodiment of the present disclosure further includes a transparent conductive layer 50 between the second semiconductor layer 23 and the DBR layer 60, and the transparent conductive layer 50 is electrically connected to the second semiconductor layer 23. The transparent conductive layer 50 may include ITO (indium tin oxide), which is beneficial to reducing the contact resistance between the second semiconductor layer 23 and the electrode, thereby improving the light-extraction efficiency of the semiconductor structure.

### Embodiment 3

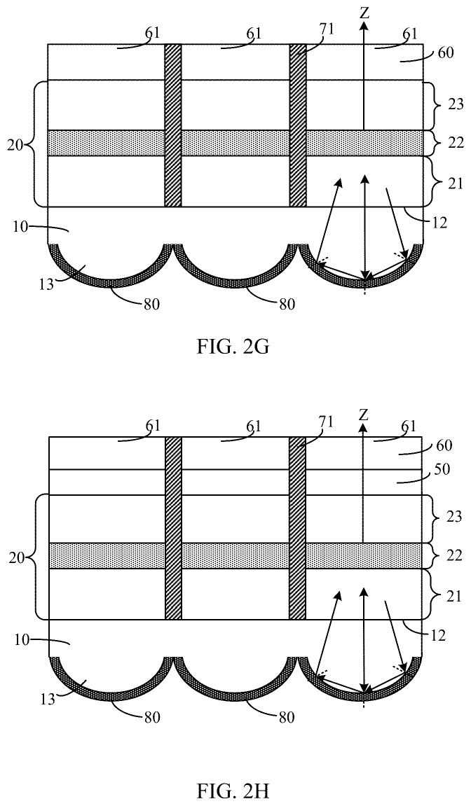

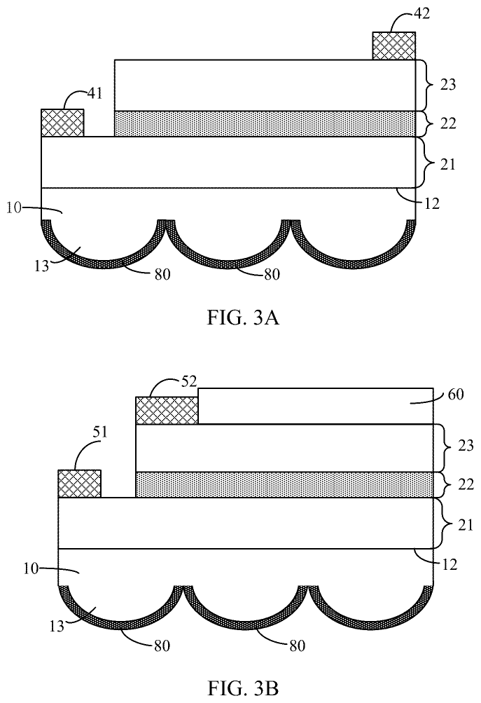

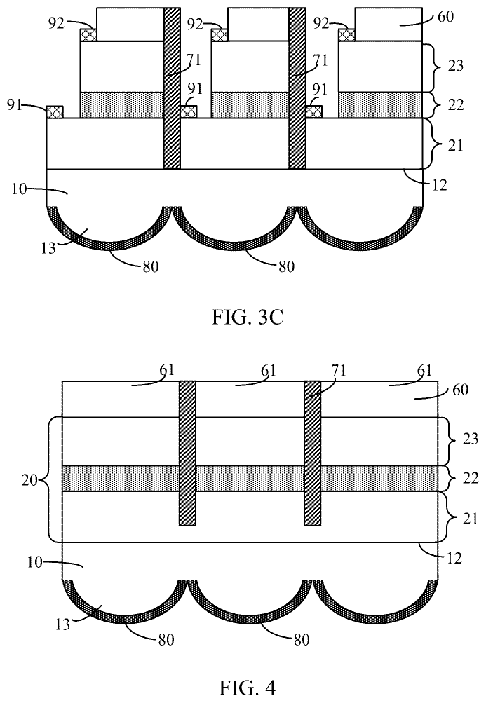

The content of the Embodiment 3 is substantially the same as the content of the Embodiments 1 and 2, and the difference between the Embodiment 3 and the Embodiments 1 and 2 is described below. As shown in FIG. 3A, FIG. 3A is schematic cross-sectional structural diagram of a semiconductor structure according to an embodiment of the present disclosure. In the embodiment shown in FIG. 3A, the light-emitting pixel layer 20 includes a light-emitting pixel, the first semiconductor layer 21 is electrically connected to a first electrode 41, and the second semiconductor layer 23 is electrically connected to a second electrode 42. The first electrode 51 and the second electrode 52 may be made of a metal, for example, conductive metals such as Ti/Al/Ni/Au, or Ni/Au.

FIG. 3B is a schematic cross-sectional structural diagram of another semiconductor structure according to an embodiment of the present disclosure. In the embodiment shown in FIG. 3B, the light-emitting pixel layer 20 includes a light-emitting pixel, the semiconductor structure includes a DBR layer 60 on the second semiconductor layer 23, the first semiconductor layer 21 is electrically connected to the first electrode 51, and the second semiconductor layer 23 is electrically connected to the second electrode 52. The first electrode 51 and the second electrode 52 may be made of a metal, for example, conductive metals such as Ti/Al/Ni/Au, or Ni/Au.

FIG. 3C is a schematic cross-sectional structural diagram of another semiconductor structure according to an embodiment of the present disclosure. In the embodiment shown in FIG. 3C, the light-emitting pixel layer 20 includes light-emitting pixels, the light-emitting pixels are separated by the isolation structures 71, and in each of the light-emitting pixels, the first semiconductor layer 21 of the light-emitting pixel is electrically connected to the first electrode 91, and the second semiconductor layer 23 of the light-emitting pixel is electrically connected to the second electrode 92. The first electrode 91 and the second electrode 92 may be made of a metal, for example, conductive metals such as Ti/Al/Ni/Au, or Ni/Au.

### Embodiment 4

The content of the Embodiment 4 is substantially the same as the content of any one of Embodiments 1 to 3, and the difference between the Embodiment 4 and the Embodiments 1 to 3 is described below. In the semiconductor structure shown in FIG. 4, the isolation structure 71 does not penetrate through the first semiconductor layer 21. In this case, it is equivalent to that all the first semiconductor layers 21 are connected together, and compared with the Embodiment 3, the manufacturing process of the electrodes can be reduced, and the common electrical connection with all the first semiconductor layers 21 can be realized through one electrode.

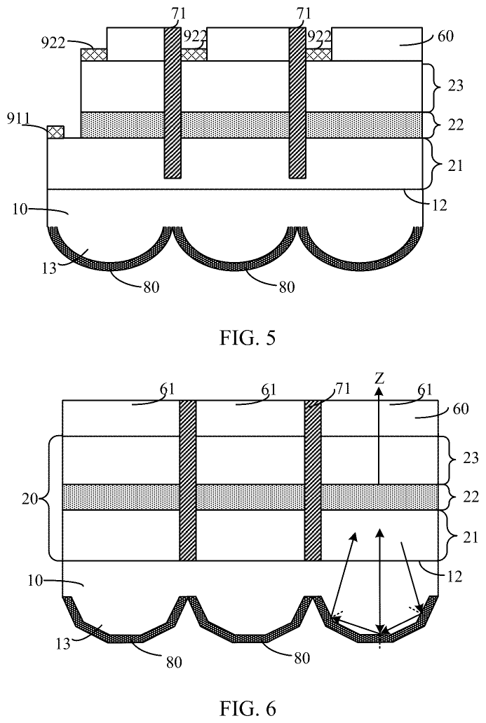

FIG. 5 is a schematic cross-sectional structural diagram of another semiconductor structure according to an embodiment of the present disclosure. In the semiconductor structure shown in FIG. 5, the isolation structure 71 does not penetrate through the first semiconductor layer 21, the common electrical connection of all the first semiconductor layers 21 can be realized by using one first electrode 911, and the second semiconductor layer 23 of each light-emitting pixel is electrically connected with the second electrode 922. The first electrode 51 and the second electrode 52 may be made of a metal, for example, conductive metals such as Ti/Al/Ni/Au, or Ni/Au.

### Embodiment 5

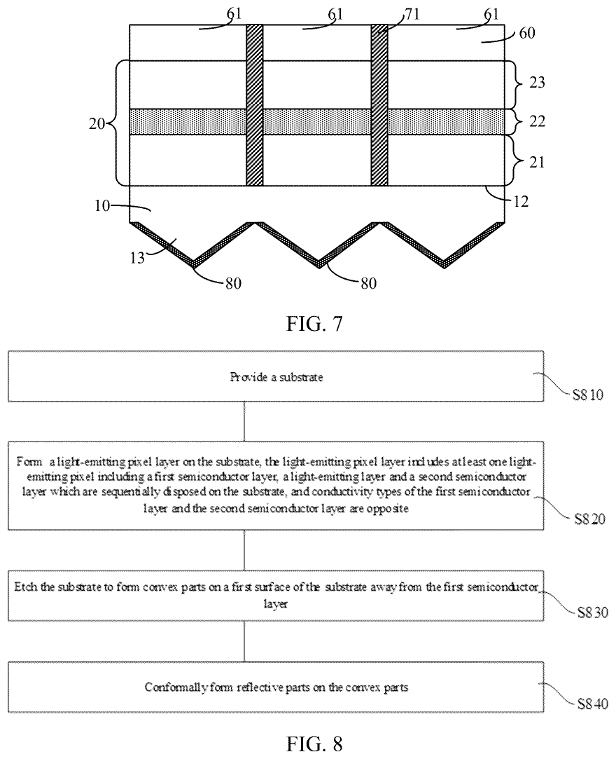

The content of the Embodiment 5 is substantially the same as the content of any one of the Embodiments 1 to 4, the difference between the Embodiment 5 and the Embodiments 1 to 4 is described below. FIGS. 6 and 7 are schematic cross-sectional structural diagrams of a semiconductor structure according to an embodiment of the present disclosure. In the semiconductor structure shown in FIGS. 6 and 7, the side of the convex part 13 away from the second surface 12 is an arc-shaped surface or a polygonal surface, that is, the surface of the reflective part 80 at a side of the convex part 13 away from the second surface 12 is an arc-shaped structure or is formed by fold lines, and the number of the fold lines forming the arc-shaped reflective part 80 is not limited in the present disclosure, as long as a convex surface similar to an arc is formed by the fold lines. Optionally, when the cross-sectional shape of a side of the convex part 13 away from the second surface 12 is a polygonal surface, the convex part 13 may be a polygonal prism structure obtained by extending the polygonal cross-section, or a hemispherical-like shape structure composed of the polygonal surfaces. By controlling the curvature of the surface of the reflective part 80, the outgoing direction or the outgoing angle of the light may be controlled, so that the reflective part 80 having a corresponding curvature may be selected according to the application scenarios with different requirements for the outgoing direction or the outgoing angle.

### Embodiment 6

Embodiment 6 of the present disclosure provides a method for manufacturing a semiconductor structure, which is used for manufacturing the semiconductor structure provided by any one of the above embodiments. FIG. 8 is a flowchart of a method for manufacturing a semiconductor structure according to an embodiment of the present disclosure. As shown in FIG. 8, the method for manufacturing the semiconductor structure includes following steps.

In step S810, a substrate is provided.

In step S820, a light-emitting pixel layer is formed on the substrate, the light-emitting pixel layer includes at least one light-emitting pixel including a first semiconductor layer, a light-emitting layer and a second semiconductor layer which are sequentially disposed on the substrate, and conductivity types of the first semiconductor layer and the second semiconductor layer are opposite.

In step S830, the substrate is etched to form convex parts on a first surface of the substrate away from the first semiconductor layer.

In step S840, reflective parts are conformally formed on the convex parts. The reflective parts and the convex parts are in one-to-one correspondence in position. The reflective part is used for reflecting the light emitted by the light-emitting pixel and adjusting an outgoing direction and/or an outgoing angle of the light.

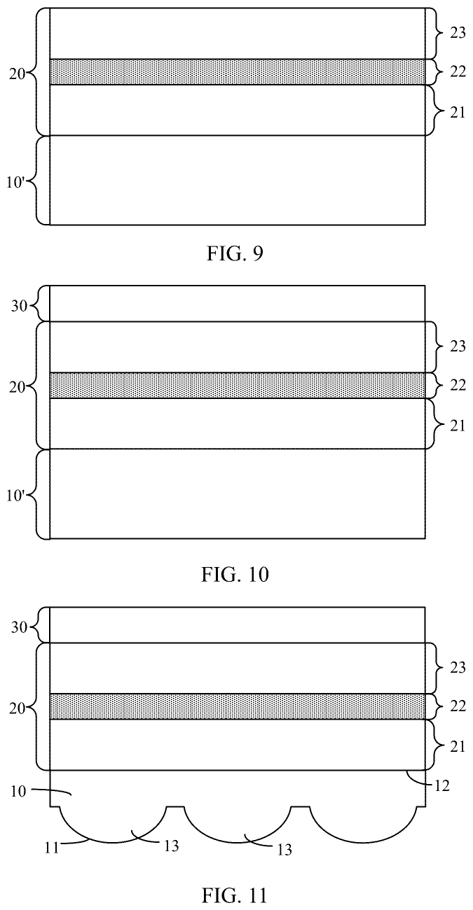

FIG. 9 to FIG. 14 are schematic diagrams of intermediate structures formed during the manufacturing process of the semiconductor structure according to an embodiment.

As shown in FIG. 9, providing a substrate 10′, and forming a light-emitting pixel layer on the substrate 10′ includes: sequentially forming a first semiconductor layer 21, a light-emitting layer 22, and a second semiconductor layer 23 on the substrate 10′, where the light-emitting pixel layer 20 includes at least one light-emitting pixel, and the conductivity types of the first semiconductor layer 21 and the second semiconductor layer 23 are opposite.

In some embodiments, the substrate 10′ is transparent, and the substrate 10′ is made of at least one of sapphire, silicon, silicon carbide, a GaN-based material, or AlN.

In some embodiments, the first semiconductor layer 21 may be an N-type semiconductor layer, the light emitting layer 22 may be a single quantum well layer or a multiple quantum well layer, and the second semiconductor layer 23 may be a P-type semiconductor layer. The first semiconductor layer 21, the light emitting layer 22 and the second semiconductor layer 23 may be made of at least one of GaN, AlN, InN, AlGaN, InGaN, AlInN, AlInGaN, GaAs or AlGaAs, and the forming process may refer to the abovementioned embodiments, and details are not described herein again.

In some embodiments, after the intermediate structure shown in FIG. 9 is acquired, as shown in FIG. 10, a support substrate 30 is bonded to the second semiconductor layer 23. The material of the support substrate 30 may be the same as or different from the material of the substrate 10′, which is not limited in the present disclosure.

In some embodiments, after the intermediate structure shown in FIG. 10 is acquired, as shown in FIG. 11, the substrate 10′ is etched to form convex parts 13 on the first surface 11 of the substrate 10′ away from the first semiconductor layer 21, thereby acquiring the substrate 10. As shown in FIG. 11, each convex part 13 protrudes in a direction away from the second surface 12 of the substrate 10. The shape of the convex part 13 may be a partial sphere or a partial cylinder. Optionally, before the substrate 10′ is etched, the substrate 10′ may be thinned, and a smaller thickness of the substrate may play a better role in converging light.

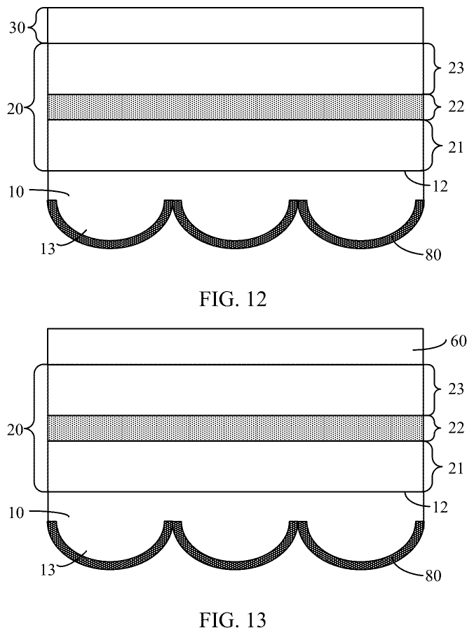

In some embodiments, after the intermediate structure shown in FIG. 11 is acquired, as shown in FIG. 12, the reflective parts 80 are conformally formed on the convex parts 13 respectively, and the reflective parts 80 and the convex parts 13 are in one-to-one correspondence in position. An orthographic projection of a reflective part 80 on the second surface 12 may coincide with an orthographic projection of a convex part 13 on the second surface 12. The reflective part 80 may be an Ag layer for reflecting light. The reflective part 80 may include at least two alternating layers, where one layer is made of Ni, and the other layer is made of Ag.

In some embodiments, after the intermediate structure shown in FIG. 12 is acquired, the support substrate 30 is stripped to acquire the semiconductor structure shown in FIG. 1A.

In some embodiments, after the semiconductor structure shown in FIG. 1A is acquired, further referring to FIG. 3A, the light-emitting layer 22 and the second semiconductor layer 23 may be etched to expose a partial region of the first semiconductor layer 21, a first electrode 41 is formed in the exposed region of the first semiconductor layer 21, and the first electrode 41 is electrically connected to the first semiconductor layer 21; and a second electrode 42 is formed on the second semiconductor layer 23, and the second electrode 42 is electrically connected to the second semiconductor layer 23. The first electrode 51 and the second electrode 52 may be made of a metal, for example, conductive metals such as Ti/Al/Ni/Au, or Ni/Au.

In some embodiments, after the semiconductor structure shown in FIG. 1A is acquired, as shown in FIG. 13, a DBR layer 60 is formed on the second semiconductor layer 23. To make the light emit out from the front surface of the semiconductor structure, the reflectivity of the DBR layer 60 is smaller than the reflectivity of the reflective part 80, for example, the reflective part 80 may be an Ag layer, and the DBR layer may be a stacked material layers of SiO₂/SiN. In this way, through the synergistic effect of the arc-shaped reflective part 80 at bottom and the DBR layer 60 at the top, the divergence angle of the light emitted by the light emitting layer 22 can be controlled, thereby improving the collimation of the light emitted by the semiconductor structure.

In some embodiments, before forming the DBR layer 60, a transparent conductive layer 50 is formed on a surface of the second semiconductor layer 23 away from the substrate 10. Further referring to FIG. 2H, the transparent conductive layer 50 is electrically connected to the second semiconductor layer 23. The transparent conductive layer 50 includes ITO (indium tin oxide), which is beneficial to reduce the contact resistance between the second semiconductor layer 23 and the electrode.

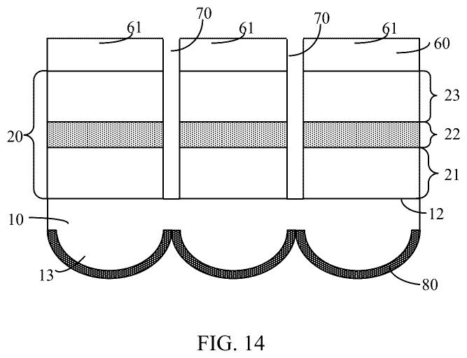

In some embodiments, after the intermediate structure shown in FIG. 13 is acquired, as shown in FIG. 14, the DBR layer 60, the second semiconductor layer 23, the light emitting layer 22, and the first semiconductor layer 21 are etched to acquire grooves 70. In some embodiments, as shown in FIG. 2G, isolation structures 71 are respectively filled in the grooves 70, that is, the isolation structures 71 are provided between adjacent light-emitting pixels, and the isolation structures 71 are used for isolating light rays of the adjacent light-emitting pixels, to avoid the crosstalk between the adjacent light-emitting pixels. The isolation structure 71 may be made of an insulating black glue. After the isolation structure 71 is filled, at least one DBR structure 61 included in the DBR layer 60 is separated by the isolation structure 71, and the at least one DBR structure 61 and the at least one light-emitting pixel are in one-to-one correspondence in position. In other words, an orthographic projection of a DBR structure 61 on the second surface 12 coincides with an orthographic projection of a light-emitting pixel on the second surface 12. In other embodiments, if the light-emitting pixels are not used for displaying images, but are only used for emitting light, the isolation structure between the adjacent light-emitting pixels may not be provided. In some embodiments, referring to FIG. 2H, the DBR layer 60, the transparent conductive layer 50, the second semiconductor layer 23, the light emitting layer 22, and the first semiconductor layer 21 may be etched to acquire grooves 70. In some embodiments, referring to FIG. 2A, the second semiconductor layer 23, the light emitting layer 22, and the first semiconductor layer 21 may be etched to acquire grooves 70.

In some embodiments, the convex parts 13, the light-emitting pixels, and the DBR structures 61 may be in one-to-one correspondence in position, that is, orthographic projections of the convex parts 13, the light-emitting pixels, and the DBR structures 61 on the second surface 12 coincide with each other and are in one-to-one correspondence.

In some embodiments, after the semiconductor structure shown in FIG. 13 is acquired, further referring to FIG. 3B, the light-emitting layer 22, the second semiconductor layer 23 and the DBR layer 60 may be etched to expose a partial region of the first semiconductor layer 21, a first electrode 51 is formed on the exposed region of the first semiconductor layer 21, and the first electrode 51 is electrically connected to the first semiconductor layer 21; and the DBR layer 60 is etched again to expose the second semiconductor layer 23, a second electrode 52 is formed on the exposed second semiconductor layer 23, and the second electrode 52 is electrically connected to the second semiconductor layer 23. The first electrode 51 and the second electrode 52 may be made of a metal, for example, conductive metals such as Ti/Al/Ni/Au, or Ni/Au.

In some embodiments, after the semiconductor structure shown in FIG. 2G is acquired, further referring to FIG. 3C, the DBR layer 60, the second semiconductor layer 23, and the light-emitting layer 22 may be etched to expose a portion of the first semiconductor layer 21 in each light-emitting pixel; a first electrode 91 electrically connected to the first semiconductor layer 21 is formed on the exposed first semiconductor layer 21 in each light-emitting pixel; the DBR layer 60 is etched again to expose a portion of the second semiconductor layer 23 in each light-emitting pixel; and a second electrode 92 electrically connected to the second semiconductor layer 23 is formed on the exposed second semiconductor layer 23 in each light-emitting pixel. The first electrode 51 and the second electrode 52 may be made of a metal, for example, conductive metals such as Ti/Al/Ni/Au, or Ni/Au.

### Embodiment 7

Embodiment 7 of the present disclosure further provides a method for manufacturing a semiconductor structure. The difference between this method for manufacturing the semiconductor structure and the method for manufacturing the semiconductor structure shown in FIG. 8 includes that: before the substrate 10′ is etched, a DBR layer 60 is formed on a side of the second semiconductor layer 23 away from the substrate 10′; after the DBR layer 60 is formed, the DBR layer 60 and the light-emitting pixel layer 20 are etched to acquire grooves 70; after the grooves 70 are respectively filled with an isolation material (for example, the insulating black glue) to acquire isolation structures 71, a support substrate 30 is bonded to a side of the DBR layer 60 away from the substrate 10′; after bonding the support substrate 30 is completed, the substrate 10′ is etched to acquire a substrate 10; reflective parts 80 are deposited on the first surface 11 of the substrate 10; and after the reflective parts 80 are acquired, the support substrate 30 is stripped.

### Embodiment 8

Embodiment 8 of the present disclosure further provides a method for manufacturing a semiconductor structure. The difference between this method for manufacturing the semiconductor structure and the method for manufacturing of the semiconductor structure shown in FIG. 8 includes that: before the substrate 10′ is etched, a transparent conductive layer 50 is formed on a side of the second semiconductor layer 23 away from the substrate 10′; a DBR layer 60 is formed on a side of the transparent conductive layer 50 away from the substrate 10′; after the DBR layer 60 is formed, the DBR layer 60, the transparent conductive layer 50 and the light-emitting pixel layer 20 are etched to acquire grooves 70; after the grooves 70 are respectively filled with an isolation material (for example, the insulating black glue) to acquire isolation structures 71, a support substrate 30 is bonded to a side of the DBR layer 60 away from the substrate 10′; after bonding the support substrate 30 is completed, the substrate 10′ is etched to acquire a substrate 10; reflective parts 80 are deposited on the first surface 11 of the substrate 10; and after the reflective parts 80 are acquired, the support substrate 30 is stripped.

The embodiments in this specification are described in a progressive manner, each embodiment focuses on the differences from other embodiments, and the same or similar part of the embodiments may refer to each other. For the method disclosed in the embodiments, since it corresponds to the structure of the product disclosed in the embodiments, the description is relatively simple, and reference may be made to the description of the structure of the product. The implementation sequence of some steps in the method embodiment can be adjusted as long as the corresponding product structure can be obtained.

The above description of the disclosed embodiments enables those skilled in the art to implement or use the present disclosure. Various modifications to these embodiments will be apparent to those skilled in the art, and the general principles defined herein may be implemented in other embodiments without departing from the spirit or the scope of the present disclosure. Thus, the present disclosure will not be limited to the embodiments shown herein but will be subject to the widest scope consistent with the principles and novel features disclosed herein.

What is claimed is:

1. A semiconductor structure, comprising:
a substrate comprising a first surface and a second surface opposite to the first surface, wherein the first surface comprises convex parts, and each of the convex parts protrudes in a direction away from the second surface;
a light-emitting pixel layer on the second surface, wherein the light-emitting pixel layer comprises at least one light-emitting pixel each comprising a first semiconductor layer, a light-emitting layer and a second semiconductor layer which are sequentially disposed on the second surface, and the conductivity types of the first semiconductor layer and the second semiconductor layer are opposite; and
reflective parts conformally formed on the convex parts, wherein the reflective parts and the convex parts are in one-to-one correspondence in position.

2. The semiconductor structure according to claim 1, wherein one of the convex parts has a different size than another of the convex parts.

3. The semiconductor structure according to claim 1, wherein the convex part comprises sub-layers with different refractive indexes.

4. The semiconductor structure according to claim 1, wherein the light-emitting pixel layer comprises light-emitting pixels, a projection area of one of the light-emitting pixels on a plane of the substrate is different from a projection area of another of the light-emitting pixels on the plane of the substrate.

5. The semiconductor structure according to claim 4, wherein a curvature radius and a thickness of a convex part corresponding to a first light-emitting pixel of the light-emitting pixels with a first projection area on the plane of the substrate are both same as a curvature radius and a thickness of a convex part corresponding to a second light-emitting pixel of the light-emitting pixels with a second projection area on the plane of the substrate, and a width of the convex part corresponding to the first light-emitting pixel is smaller than a width of the convex part corresponding to the second light-emitting pixel, wherein the first projection area is smaller than the second projection area.

6. The semiconductor structure according to claim 4, wherein a curvature radius and a thickness of a convex part corresponding to a first light-emitting pixel of the light-emitting pixels with a first projection area on the plane of the substrate are both smaller than a curvature radius and a thickness of a convex part corresponding to a second light-emitting pixel of the light-emitting pixels with a second projection area on the plane of the substrate, and a width of the convex part corresponding to the first light-emitting pixel is smaller than a width of the convex part corresponding to the second light-emitting pixel, wherein the first projection area is smaller than the second projection area.

7. The semiconductor structure according to claim 1, further comprising:
a DBR layer on the second semiconductor layer, wherein the DBR layer comprises at least one DBR structure, and the at least one DBR structure and the at least one light-emitting pixel are in one-to-one correspondence in position.

8. The semiconductor structure according to claim 1, further comprising:
an isolation structure between adjacent light-emitting pixels, wherein the isolation structure is configured to isolate light emitted by the adjacent light-emitting pixels.

9. The semiconductor structure according to claim 1, further comprising:
a first electrode electrically connected to the first semiconductor layer; and
a second electrode electrically connected to the second semiconductor layer.

10. The semiconductor structure according to claim 1, wherein for each of the convex parts, a side of the convex part away from the second surface is an arc-shaped surface or a polygonal surface.

11. The semiconductor structure according to claim 1, wherein a distance from the light-emitting layer to the convex part is x times a curvature radius of the convex part, and a value of the x ranges from 0.3 to 1.

12. The semiconductor structure according to claim 11, wherein the light-emitting layer is on a focal plane of the convex part, and a distance from the light-emitting layer to the convex part is 0.5 times the curvature radius of the convex part.

13. The semiconductor structure according to claim 12, wherein the light-emitting pixel layer comprises light-emitting pixels, light-emitting colors of the light-emitting pixels comprise red, blue or green, a thickness of a convex part corresponding to a red light-emitting pixel is greater than a thickness of a convex part corresponding to a green light-emitting pixel, and the thickness of the convex part corresponding to the green light-emitting pixel is greater than a thickness of a convex part corresponding to the blue light-emitting pixel.

14. A method for manufacturing a semiconductor structure, comprising:
providing a substrate;
forming a light-emitting pixel layer on the substrate, wherein the light-emitting pixel layer comprises at least one light-emitting pixel comprising a first semiconductor layer, a light-emitting layer and a second semiconductor layer which are sequentially disposed on the substrate, and conductivity types of the first semiconductor layer and the second semiconductor layer are opposite;
etching the substrate to form convex parts a first surface of the substrate away from the first semiconductor layer; and
conformally forming reflection parts on the convex parts, wherein the reflection parts and the convex parts are in one-to-one correspondence in position.

15. The method according to claim 14, further comprising:
etching the light emitting layer and the second semiconductor layer to expose a partial region of the first semiconductor layer;
forming a first electrode on an exposed region of the first semiconductor layer, wherein the first electrode is electrically connected to the first semiconductor layer; and
forming a second electrode on the second semiconductor layer, wherein the second electrode is electrically connected to the second semiconductor layer.

16. The method according to claim 14, further comprising:
etching the second semiconductor layer, the light emitting layer, and the first semiconductor layer to acquire grooves; and
filling the grooves with isolation structures, respectively, wherein the isolation structure is configured to isolate light emitted by adjacent light-emitting pixels.

17. The method according to claim 14, further comprising:
forming a DBR layer on a surface of the second semiconductor layer away from the substrate;
wherein a reflectivity of the reflective parts is greater than a reflectivity of the DBR layer.

18. The method according to claim 17, further comprising:
forming a transparent conductive layer on a surface of the second semiconductor layer away from the substrate; and
forming the DBR layer on a surface of the transparent conductive layer away from the substrate.

19. The method according to claim 17, further comprising:
etching the DBR layer, the second semiconductor layer, the light emitting layer, and the first semiconductor layer to acquire grooves; and
filling the grooves with isolation structures, respectively, wherein at least one DBR structure comprised in the DBR layer is respectively separated by the isolation structures, and the at least one DBR structure and the at least one light-emitting pixel are in one-to-one correspondence in position.

20. The method according to claim 19, further comprising:
etching the DBR layer, the second semiconductor layer, and the light-emitting layer to expose a portion of the first semiconductor layer in each light-emitting pixel;
forming a first electrode electrically connected to the first semiconductor layer on the first semiconductor layer exposed in each light-emitting pixel;
performing secondary etching at the DBR layer to expose a part of the second semiconductor layer in each light-emitting pixel; and
forming a second electrode electrically connected to the second semiconductor layer on the exposed second semiconductor layer in each light-emitting pixel.
